(19) United States
(12) Patent Application Publication
(10) Pub. No.: US 2017/0184893 A1
(43) Pub. Date: Jun. 29, 2017

(54) SEMICONDUCTOR APPARATUS, METHOD OF MANUFACTURING SAME, AND LIQUID CRYSTAL DISPLAY APPARATUS

(71) Applicant: Sharp Kabushiki Kaisha, Osaka (JP)

(72) Inventors: Takao SAITOH, Osaka (JP); Seiji KANEKO, Osaka (JP); Yohsuke KANZAKI, Osaka (JP); Yutaka TAKAMARU, Osaka (JP); Keisuke IDE, Osaka (JP); Takuya MATSUO, Osaka (JP)

(73) Assignee: Sharp Kabushiki Kaisha, Osaka (JP)

(21) Appl. No.: 15/325,215

(22) PCT Filed: Jul. 2, 2015
(86) PCT No.: PCT/JP2015/069142

§ 371 Date: Jan. 10, 2017

(30) Foreign Application Priority Data
Jul. 11, 2014 (JP) 2014-143272

(51) Int. Cl. G02F 1/1368; H01L 29/66; G02F 1/1343; H01L 27/12; G02F 1/1333; G02F 1/133

(52) U.S. Cl. CPC G02F 1/1368; G02F 1/133345; G02F 1/13306; G02F 1/134309; H01L 27/1225; H01L 27/127; H01L 27/1237; H01L 29/66969; G02F 2202/10

(57) ABSTRACT

A semiconductor device includes a substrate, a first thin film transistor supported on the substrate and having a first active layer that primarily contains a first oxide semiconductor, and second thin film transistor supported on the substrate and having a second active layer that primarily contains a second oxide semiconductor with a higher mobility than the first oxide semiconductor. The first active layer and the second active layer are positioned on the same insulating layer and contact the same insulating layer.

### TECHNICAL FIELD

The present invention relates to a semiconductor device, a method of manufacturing the same, and a liquid crystal display device.

### BACKGROUND ART

An active matrix substrate includes a thin film transistor (TFT) as a switching device for each pixel thereon, for example. In the present specification, this type of TFT is referred to as “pixel TFT.”

A portion or all of the peripheral driver circuits are sometimes integrally formed on the same substrate with the pixel TFTs. This type of active matrix substrate is called a driver monolithic active matrix substrate. In driver monolithic active matrix substrates, the peripheral driver circuits are disposed in an area (non-display area or frame region) outside the area containing the plurality of pixels (display area). The pixel TFTs and the TFTs constituting the driver circuits (hereinafter, “circuit TFTs”) can be formed using the same semiconductor film. A polysilicon film, which has high electron field-effect mobility, is used for this semiconductor film, for example.

Furthermore, the use of an oxide semiconductor as the material of the TFT active layer, instead of amorphous silicon or polysilicon, has been recently proposed. There is a proposal to use an In—Ga—Zn—O semiconductor, which has indium, gallium, zinc, and oxygen as primary components, as the oxide semiconductor. Moreover, there is also a proposal to use an oxide semiconductor with a higher mobility than an In—Ga—Zn—O semiconductor (such as an In—Sn—Zn—O semiconductor). Such a TFT is referred to as an “oxide semiconductor TFT.” The oxide semiconductors have a higher mobility than amorphous silicon. Therefore, the oxide semiconductor TFTs can operate at a faster speed than the amorphous silicon TFTs. Because an oxide semiconductor film can be formed by a simpler process than a polysilicon film, the oxide semiconductor film can be employed in a device requiring a large surface area. Accordingly, by using the oxide semiconductor film, it is also possible to integrally form the pixel TFTs and circuit TFTs on the same substrate.

Regardless of whether a polysilicon film or oxide semiconductor film is used, however, it is difficult to sufficiently satisfy the characteristics that are demanded for both pixel TFTs and circuit TFTs.

As a countermeasure, Patent Document 1 discloses an active matrix liquid crystal panel that includes oxide semiconductor TFTs as pixel TFTs and TFTs that use a non-oxide semiconductor film as an active layer as circuit TFTs (e.g., crystalline silicon TFTs). Patent Document 1 describes that using the oxide semiconductor TFTs as pixel TFTs can inhibit uneven display, and using the crystalline silicon TFTs as circuit TFTs can enable high-speed driving.

Furthermore, Patent Document 2 proposes using two types of oxide semiconductor layers with differing carrier concentrations on an active matrix substrate in an organic electroluminescent display device. Specifically, Patent Document 2 discloses forming the active layer of the circuit TFTs, which require high mobility, with a multilayer structure that includes a high carrier concentration oxide semiconductor layer and a low carrier concentration oxide semiconductor layer, and forming the active layer of the pixel TFTs, which require uniform characteristics, with only a low carrier concentration oxide semiconductor layer.

### RELATED ART DOCUMENTS

### Patent Documents

Patent Document 1: Japanese Patent Application Laid-Open Publication No. 2010-3910
Patent Document 2: Japanese Patent Application Laid-Open Publication No. 2010-161327

### SUMMARY OF THE INVENTION

### Problems to be Solved by the Invention

There has been demand recently for liquid crystal panels, such as in smartphones, to have an even narrower frame and to consume less power. “Narrowing” the frame refers to shrinking the surface area required for the driver circuits in order to shrink the area (frame region) outside the display area. The inventors of the present invention have found that it is difficult to reduce power consumption while further narrowing the frame in conventional active matrix substrates. Specific details will be described later.

One embodiment of the present invention was made in view of the above-mentioned conditions and aims at providing a novel semiconductor device that can reconcile a reduction in power consumption with a narrower frame.

### Means for Solving the Problems

A semiconductor device of one embodiment of the present invention includes: a substrate; a first thin film transistor supported on the substrate and having a first active layer that primarily contains a first oxide semiconductor; and a second thin film transistor supported on the substrate and having a second active layer that primarily contains a second oxide semiconductor with a mobility that is higher than the first oxide semiconductor, wherein the first active layer and the second active layer are positioned on a same insulating layer and contact the same insulating layer.

In one embodiment, an OFF current of the first thin film transistor when illuminated by visible light may be less than an OFF current of the second thin film transistor when illuminated by visible light.

An OFF current of the first thin film transistor when illuminated by light with a wavelength of 450 nm and an intensity of 50 lux may be less than an OFF current of the second thin film transistor when illuminated by light with a wavelength of 450 nm and an intensity of 50 lux.

The mobility of the second oxide semiconductor may be greater than 10 cm²/Vs.

An OFF current of the first thin film transistor when illuminated by light with a wavelength of 450 nm and an intensity of 50 lux may be less than or equal to 1×10⁻¹³ amperes.

The first oxide semiconductor may be an In—Ga—Zn—O semiconductor.

The second oxide semiconductor may be an In—Sn—Zn—O semiconductor.

The first and second oxide semiconductors may both be In—Ga—Zn—O semiconductors, and a mole ratio of indium to all metal elements in the first oxide semiconductor may be smaller than a mole ratio of indium to all metal elements in the second oxide semiconductor.

A gate electrode of the first thin film transistor and a gate electrode of the second thin film transistor may be positioned on a side of the first and second active layers facing the substrate.

The second thin film transistor may further include another gate electrode positioned on a side of the second active layer opposite to the substrate.

In one embodiment, the semiconductor device further includes a display area having a plurality of pixels, and a driver circuit formation area disposed in an area outside the display area and having a driver circuit, wherein the second thin film transistor forms the driver circuit in the driver circuit formation area, and wherein the first thin film transistor is positioned in the respective pixels in the display area.

The semiconductor device may further include a backlight on a rear surface side of the substrate.

A liquid crystal display device of one embodiment of the present invention includes the semiconductor device, and the liquid crystal display device includes: an opposite substrate held so as to face the substrate; a liquid crystal layer between the substrate and the opposite substrate; and a backlight on a rear surface side of the substrate.

A method of manufacturing a semiconductor device including a first film transistor and a second thin film transistor includes: (A) forming, on a substrate having an insulating surface, gate electrodes of the first and second thin film transistors and a gate insulating layer covering the gate electrodes of the first and second thin film transistors; (B) forming, on the gate insulating layer, a first active film of the first thin film transistor and a second active film of the second thin film transistor in this order or an opposite order; (b1) forming a first film made of a first oxide semiconductor and patterning the first film to form the first active layer; (b2) forming a second film made of a second oxide semiconductor with a mobility that is higher than the first oxide semiconductor and patterning the second film to form the second active layer; and (C) forming, on the first and second active layers, source electrodes and drain electrodes of the first and second thin film transistors.

In one embodiment, a first etchant is used to pattern the first film in the step (b1) of forming the first film, and a second etchant that differs from the first etchant is used to pattern the second film in the step (b2) of forming the second film.

In one embodiment, the first oxide semiconductor is an In—Ga—Zn—O semiconductor, and the second oxide semiconductor is an In—Sn—Zn—O semiconductor, and the first etchant is a nitric phosphoric acid etchant and the second etchant is oxalic acid.

In one embodiment, the step (B) of forming the first active film and the second active film further includes performing a first heat treatment on the first active layer or the first film and performing a second heat treatment on the second active layer or the second film, the first heat treatment and the second heat treatment being performed simultaneously.

### Effects of the Invention

One embodiment of the present invention makes it possible to provide a novel semiconductor device that can reconcile a reduction in power consumption with a narrower frame.

### BRIEF DESCRIPTION OF THE DRAWINGS

FIG. 1 is a schematic cross-sectional view showing an example of a first TFT 10A and second TFT 10B in a semiconductor device 100 of Embodiment 1.

FIG. 2 is a schematic plan view showing an example of a semiconductor device (active matrix substrate) 200 of Embodiment 1.

FIG. 3 is a schematic cross-sectional view showing an example of a semiconductor device 200 of Embodiment 1.

FIG. 4 is a cross section showing an example of a liquid crystal display device that includes the semiconductor device 200.

FIGS. 5(a) to (f) are schematic cross-sectional views for explaining steps in the manufacturing process of the semiconductor device 200.

FIGS. 6(a) to (c) are schematic cross-sectional views for explaining steps in the manufacturing process of the semiconductor device 200.

FIG. 7 is a view showing an example of a process flow of the respective TFTs in the semiconductor device 200.

FIG. 8(a) is a cross-sectional view showing an example of the respective TFTs in a semiconductor device (active matrix substrate) 300 of Embodiment 2, and FIG. 8(b) is a plan view of a second TFT 20B.

FIG. 9(a) is a view showing an example of characteristics of a conventional high mobility oxide semiconductor TFT during light illumination, and FIG. 9(b) is a view showing a relationship between wavelength and intensity of the LED light used for the light illumination.

### DETAILED DESCRIPTION OF EMBODIMENTS

Depending on how the liquid crystal panel is used, the demands for a liquid crystal panel that uses a driver monolithic active matrix substrate are (1) narrow frame and (2) low power consumption. The inventors of the present invention researched the structure for an active matrix substrate that can satisfy both these demands, and had the following findings.

Further improvement in mobility of the active layer in the circuit TFTs can shrink the surface area required for the driver circuits and allow further frame narrowing. It is believed that using an oxide semiconductor with a higher mobility (hereinafter, “high mobility oxide semiconductor”) than an In—Ga—Zn—O semiconductor as the material for the active layer can make it possible to further shrink the frame region, for example.

Furthermore, in an active matrix substrate using oxide semiconductor TFTs as pixel TFTs, because oxide semiconductor TFTs have excellent OFF leakage characteristics, it is possible to perform driving that reduces the writing frequency (low-frequency driving) for the respective pixels. This makes it possible to reduce the power consumption.

However, the inventors of the present invention have found that using high mobility oxide semiconductor TFTs as pixel TFTs may make it difficult to perform low-frequency driving. Upon further investigation into the cause of this, it was found that, in high mobility oxide semiconductor TFTs, there is a large OFF leakage current when the TFTs are illuminated by light.

This problem will be described in more detail below with reference to the drawings.

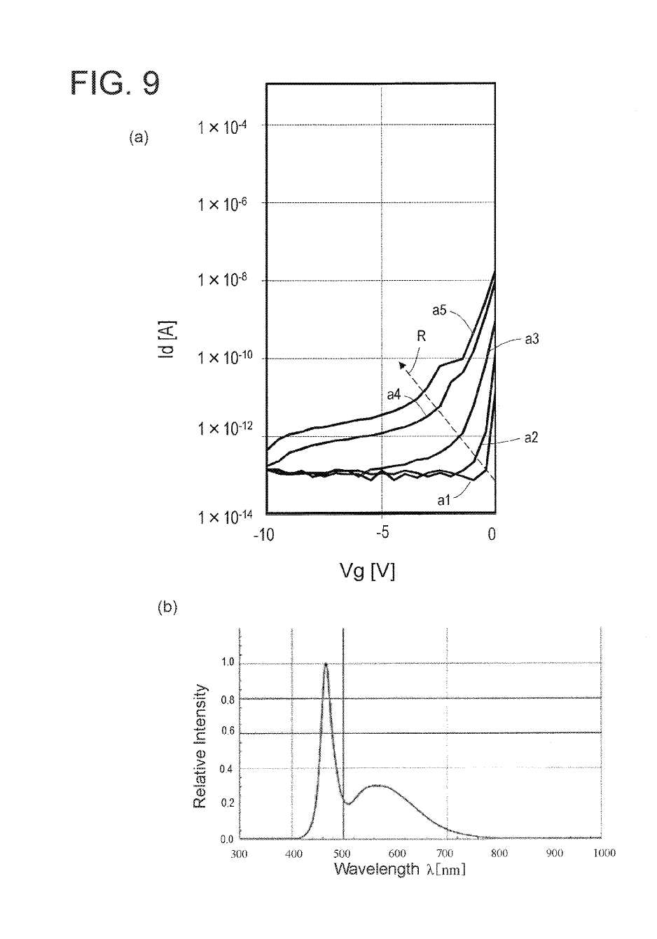

FIG. 9(a) is a graph showing OFF V-I characteristics when the high mobility oxide semiconductor TFT is illuminated by light. The measurement results of the V-I characteristics shown here are for a high mobility oxide semiconductor TFT that uses an In—Sn—Zn—O semiconductor (mobility: approx. 30 cm²/Vs). The horizontal axis is gate voltage and the vertical axis is drain current.

During measurement, LED lights of differing intensities illuminated the substrate of the high mobility oxide semiconductor TFT. FIG. 9(b) shows the relationship between wavelength and intensity of the LED lights that were used.

In the measurement results shown by the graph in FIG. 9(a), line a1 is a state of no illumination, line a2 is illumination with an intensity of 50 lux, line a3 is illumination with an intensity of 1,000 lux, line a4 is illumination with an intensity of 5,000 lux, and line a5 is illumination with an intensity of 10,000 lux.

As can be seen from these results, in a high mobility oxide semiconductor TFT, there is almost no OFF current during a state of no illumination (line a1). Line a1 does appear to show an OFF current exceeding 1×10⁻¹⁴ A, but this is due to noise, and the actual OFF current is lower than is shown. When the high mobility oxide semiconductor TFT is illuminated, the OFF current increases as the intensity of the light increases. When blue light (wavelength: approx. 450 nm) is used for illumination at an intensity of 50 lux, for example, the OFF current of the high mobility oxide semiconductor TFT exceeds 1×10⁻¹³[A]. When the inventors of the present invention researched other oxide semiconductors, it was found that the higher the mobility of the oxide semiconductor is, the greater the tendency there is for OFF current to increase during illumination.

Accordingly, when using a high mobility oxide semiconductor TFT as a pixel TFT, illumination by light from the backlight, for example, causes a large leakage current (OFF leakage current) to flow when the high mobility oxide semiconductor is OFF. Thus, if low-frequency driving is performed, there is a risk that during the pause periods when the rewriting operation of image data is paused, the potential of the pixels will drop due to the leakage current, and the orientation of the liquid crystal will not be possible to maintain. If writing frequency is increased in order to prevent this, then it is difficult to keep power consumption low.

Although not shown, in an In—Ga—Zn—O semiconductor with a 1:1:1 composition ratio of In, Ga, and Zn, OFF current was below detection limits (e.g., at or below 1×10⁻¹⁴[A]), even when illuminated with a blue light of 50 lux or more, for example. This result shows that OFF leakage current is extremely small even during illumination. Accordingly, when using a TFT having this oxide semiconductor as the pixel TFT, it is possible to more effectively reduce writing frequency.

Thus, the characteristics demanded for circuit TFTs and pixel TFTs are different from each other, and simultaneously satisfying both is difficult.

The inventors of the present invention have found, after extensive research based on the above findings, that it is possible to ensure power consumption while achieving an even narrower frame by using oxide semiconductors with differing mobilities for the circuit TFTs and the pixel TFTs.

### Embodiment 1

Embodiment 1 of the semiconductor device according to the present invention will be described. The semiconductor device of the present embodiment contains at least one each of two types of TFTs formed of mutually different oxide semiconductors on the same substrate. In the present specification, “semiconductor device” widely encompasses circuit substrates such as active matrix substrates, various types of display devices such as liquid crystal display devices or organic EL display devices, image sensors, electronic devices, and the like.

A configuration of a semiconductor device 100 of the present embodiment will be described using an active matrix substrate as an example below with reference to the drawings.

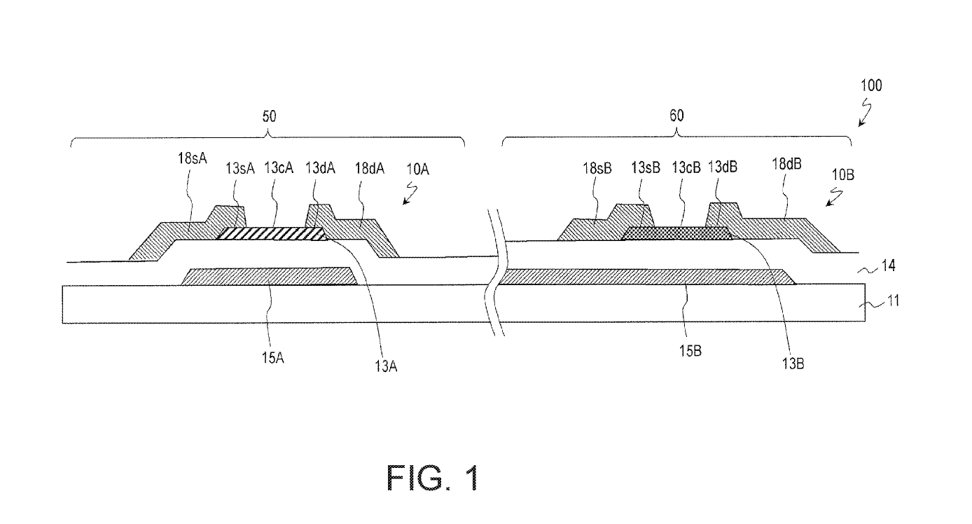

FIG. 1 is a schematic cross-sectional view showing an example of two types of TFTs in the semiconductor device 100.

The semiconductor device 100 includes a substrate 11, a first TFT 10A supported by the substrate 11, and a second TFT 10B supported by the substrate 11. The first TFT 10A has a first active layer 13A that mainly includes a first oxide semiconductor. The second TFT 10B has a second active layer 13B that mainly includes a second oxide semiconductor, which has a higher mobility than the first oxide semiconductor. The first active layer 13A and the second active layer 13B are positioned on the same insulating layer (gate insulating layer 14) and contact the top of the insulating layer 14. Furthermore, the OFF current of the first TFT 10A during visible light illumination is less than the OFF current of the second TFT during visible light illumination.

In the present specification, “active layer” refers to a semiconductor layer including a region where a channel is formed in each TFT. Alternatively, the first active layer 13A may include impurities, conductors with oxide semiconductors with partially lowered resistance, etc. in addition to the first oxide semiconductor. In a similar manner, the second active layer 13B may include impurities, conductors with oxide semiconductors with partially lowered resistance, etc. in addition to the second oxide semiconductor.

In the example shown in FIG. 1, the first TFT 10A has a gate electrode 15A formed on the substrate 11, an insulating layer 14 covering the gate electrode 15A, and the first active layer 13A positioned on the insulating layer 14. At least a portion of the first active layer 13A is positioned so as to overlap the gate electrode 15A over the insulating layer 14. The second TFT 10B has a gate electrode 15B formed on the substrate 11, an insulating layer 14 covering the gate electrode 15B, and the second active layer 13B positioned on the insulating layer 14. At least a portion of the second active layer 13B is positioned so as to overlap the gate electrode 15B over the insulating layer 14. The first active layer 13A is an In—Ga—Zn—O semiconductor, for example, and the second active layer 13B is an In—Sn—Zn—O semiconductor, for example.

Furthermore, the active layers 13A and 13B each have a region where a channel is formed (channel region) 13cA & 13cB, and source contact regions 13sA &13sB and drain contact regions 13dA & 13 dB respectively positioned on both sides of the channel region. In this example, the portions of the active layer 13A and 13B overlapping the gate electrodes 15A and 15B over the insulating layer 14 are the channel regions 13cA and 13cB, respectively. The first TFT 10A further includes a source electrode 18sA and a drain electrode 18dA connected to the source contact region 13sA and drain contact region 13dA, respectively. In a similar manner, the second TFT 10B further includes a source electrode 18sB and a drain electrode 18dB connected to the source contact region 13sB and drain contact region 13 dB, respectively.

The mobilities of the first and second oxide semiconductors have no particular limitations. The mobility of the second oxide semiconductor may be greater than 10 cm²/Vs, for example. The mobility is preferably at least 20 cm²/Vs. The mobility of the second oxide semiconductor may be less than or equal to 50 cm²/Vs, for example. In contrast, the mobility of the first oxide semiconductor may be 0.5 to 20 cm²/Vs, for example.

The OFF current during illumination of the respective TFTs 10A and 10B has no particular limitations. When illuminated under prescribed parameters, such as illumination by blue light with a wavelength of approx. 450 nm at an intensity of 50 lux, the OFF current of the first TFT 10A should be less than the OFF current of the second TFT 10B when illuminated under the same parameters. The OFF current of the first TFT 10A in the illumination parameters above is less than 1×10⁻¹³ A (amperes), for example, and preferably at or below the detection limits of the device (1×10⁻¹⁴ A). Meanwhile, the OFF current of the second TFT 10A in the illumination parameters above may be greater than 1×10⁻¹³ A (amperes), for example.

The semiconductor device 100, by having the configuration described above, makes it possible to differentiate the first and second TFTs 10A and 10B in accordance with the characteristics required of the respective TFTs. The second active layer 13B of the second TFT 10B has a higher mobility than the first active layer 13A of the first TFT 10A. If the second TFT 10B is used as a circuit TFT, for example, then it is possible to reduce the circuit surface area. Meanwhile, the first TFT 10A has a smaller OFF current during illumination than the second TFT 10B, which makes it possible to reduce power consumption if used as a pixel TFT, for example.

In Patent Document 2 described above, the active layer of the circuit TFT has a multilayer structure in which the oxide semiconductor layer with the high carrier concentration is the bottom layer and the oxide semiconductor layer with the low carrier concentration is the top layer. In this type of configuration, there is more of a risk that ON characteristics will drop as compared to if only an oxide semiconductor layer with a high carrier concentration were used as the active layer of the circuit TFT. Furthermore, it is necessary to consider the relative positioning precision of two types of oxide semiconductors during design, which makes it difficult to achieve a high-definition device. Moreover, in the configuration of Patent Document 2, the oxide semiconductor layer with the high carrier concentration (the oxide semiconductor layer where the channel is formed) has only the side face thereof directly contacting the source and drain electrodes on the active layer. Thus, it may not be possible to ensure sufficient contact area between the oxide semiconductor layer with the high carrier concentration and the source and drain electrodes. In contrast, in the present embodiment, the active layer of the second TFT 10B, which is the circuit TFT, does not actually include the first oxide semiconductor, which has relatively low mobility. Therefore, it is possible to have reliably high ON characteristics and to more effectively reduce the circuit surface area. Furthermore, the active layers of the first and second TFTs 10A and 10B are formed separately on the same insulating layer, and thus it is not necessary to consider the relative positioning between the active layers. Accordingly, it is possible to achieve a higher definition device.

The first oxide semiconductor has no particular limitations, but is a ternary oxide of In (indium), Ga (gallium), and Zn (zinc) (hereinafter, “In—Ga—Zn—O conductor”), for example. The In—Ga—Zn—O semiconductor is a ternary oxide of In (indium), Ga (gallium), and Zn (zinc). Furthermore, the crystalline structure of the In—Ga—Zn—O semiconductor has no particular limitations, but is preferably a crystalline In—Ga—Zn—O semiconductor where the c-axis is oriented mostly perpendicularly to the plane. The crystalline structure of such an In—Ga—Zn—O semiconductor is described in Japanese Patent Application Laid-Open Publication No. 2012-134475, for example. All the content disclosed in Japanese Patent Application Laid-Open Publication No. 2012-134475 is incorporated by reference in the present specification. The ratio (composition ratio) of In, Ga, and Zn has no particular limitations, and includes In:Ga:Zn=2:2:1, In:Ga:Zn=1:1:1, and In:Ga:Zn=1:1:2, and the like, for example. However, it is preferable that the composition ratio of In to all metal elements (In, Ga, and Zn) is ⅓ or below. If the composition ratio exceeds ⅓, mobility becomes higher and there is a risk that OFF current will increase during illumination.

In addition to an In—Ga—Zn—O semiconductor, a ZnO semiconductor and ZnSnO semiconductor can also be used.

In the present embodiment, a crystalline In—Ga—Zn—O semiconductor is used as the first oxide semiconductor. The composition ratio of In, Ga, and Zn is 1:1:1, for example. The composition ratio “1:1:1” described in the present specification can also include 0.8-1.2:0.8-1.2:0.8-1.2, for example. Accordingly, this also includes cases where a deviation has occurred during processing or where impurities have been doped. The mobility of this crystalline In—Ga—Zn—O semiconductor is approximately 10 cm²/Vs, for example. The OFF current of the TFT using this crystalline In—Ga—Zn—O semiconductor during illumination by blue light with a wavelength of approximately 450 nm at an intensity of 50 lux is at or below the detection limits (e.g., at or below 1×10⁻¹⁴ amperes).

The second oxide semiconductor has no particular limitations as long as it is an oxide semiconductor that has a higher mobility than the first oxide semiconductor. The second oxide semiconductor may be an oxide semiconductor containing at least one of In, Sn, Zn, Ga, Ti, Si, C, or the like, for example. The second semiconductor may alternatively be an In—Sn—Zn—O semiconductor, In—Ga—O semiconductor, In—Ti—O semiconductor, I—Sn—Ga—O semiconductor, In—Sn—O semiconductor, In—Zn—O semiconductor, Al—Zn—O semiconductor, Al—Ga—O semiconductor, or the like.

In the present embodiment, an In—Sn—Zn—O semiconductor is used as the second oxide semiconductor, for example. The composition ratio of the In, Sn, and Zn has no particular limitations, and In:Sn:Zn may be 0.1-0.9:0.1-0.9:0.1-0.9 (with the sum of In, Sn, and Zn being 1), for example. The composition and method of forming the In—Sn—Zn—O semiconductor is described in WO 2013/108630, for example. All the content disclosed in WO 2013/108630 is incorporated by reference in the present specification. The mobility of the In—Sn—Zn—O semiconductor depends on the composition ratio of In, Sn, and Zn, but is 30 cm²/Vs or above, for example. The OFF current of the TFT using this In—Sn—Zn—O semiconductor during illumination by blue light with a wavelength of approximately 450 nm at an intensity of 50 lux is approximately 1×10⁻¹³[A], for example.

Furthermore, the second oxide semiconductor may contain the same metal element as the first oxide semiconductor and may have a different composition ratio. The first oxide semiconductor and second oxide semiconductor may both be In—Ga—Zn—O semiconductors, for example. In such a case, the mole ratio of indium to all metal elements in the first oxide semiconductor may be less than the mole ratio of indium to all metal elements in the second oxide semiconductor. The mole ratio of indium to all metal elements in the first oxide semiconductor may be ⅓ or below, for example, and the mole ratio of indium to all metal elements in the second oxide semiconductor may be greater than ⅓, for example.

The first and second oxide semiconductors have no particular limitations as long as both are oxide semiconductors that satisfy the relationship between mobility and OFF current during illumination as described above. As described above, the higher the mobility of the oxide semiconductor that is used, the more of a tendency there is for the OFF current to increase during illumination of the TFT; therefore, using oxide semiconductors with differing magnitudes of mobility makes it possible to achieve similar effects to those described above. In addition to the semiconductors illustratively described above, the first and second oxide semiconductors may be Zn—Ti—O semiconductors (ZTO), Cd—Ge—O semiconductors, Cd—Pb—O semiconductors, CdO (cadmium oxide), Mg—Zn—O semiconductors, In—Ga—Sn—O semiconductors, or the like, for example.

In the example shown in FIG. 1, the first TFT 10A and second TFT 10B both have a bottom-gate structure in which the gate electrodes 15A and 15B are positioned on the substrate 11 side of the active layers 13A and 13B. In such a case, the insulating layer 14 functions as the gate insulating layer of the first TFT 10A and second TFT 10B. Furthermore, the first TFT 10A and second TFT 10B both have a top-contact structure in which the top of the active layers 13A and 13B contact the source and drain electrodes.

The semiconductor device of the present embodiment is not limited to the configurations described above. Alternatively, one or both of the first TFT 10A and second TFT 10B may have a top-gate structure, or a double-gate structure in which a gate is both above and below the active layer. Moreover, one or both of the first TFT 10A and second TFT 10B may have a bottom-contact structure in which the bottom of the active layers 13A and 13B contact the source and drain electrodes.

The first and second TFTs 10A and 10B may have the same TFT structure. Alternatively, the TFTs may have mutually different TFT structures (e.g., the first TFT 10A having a bottom-gate structure and the second TFT 10B having a double-gate structure, or the like).

<Active Matrix Substrate>

The present embodiment can be applied to an active matrix substrate, for example. Below, with reference to figures, one example of an active matrix substrate of the present invention will be described.

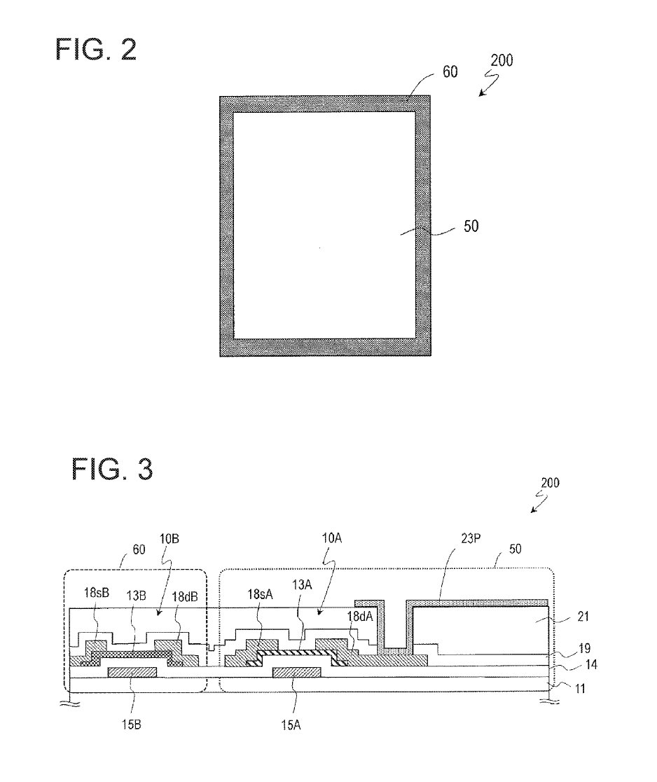

FIG. 2 is a schematic plan view showing one example of an active matrix substrate 200 of the present embodiment. FIG. 3 is a cross-sectional view of first and second TFTs 10A and 10B on the active matrix substrate 200. The same reference characters are given to constituting elements that are similar to FIG. 1.

The active matrix substrate 200 includes a display area 50 where a plurality of pixels are arrayed, and an area outside the display area 50 (hereinafter, “non-display area”) 60. Although not shown, the non-display area has circuits such as gate driver circuits, inspection circuits, and source switching circuits disposed therein, for example. The display area 50 has formed therein a plurality of gate bus lines extending in the row direction (not shown) and a plurality of source bus lines extending in the column direction. Although not shown, the pixels are respectively defined by the gate bus lines and source bus lines, for example. The gate bus lines each connect to respective terminals of the gate driver circuit.

In the active matrix substrate 200, the first TFT 10A is formed in each pixel in the display area 50 as a pixel TFT. Furthermore, in the non-display area 60, the second TFT 10B is formed the circuit TFT constituting the driver circuit. The active matrix substrate 200 of the present embodiment should include at least one first TFT 10A and at least one second TFT 10B.

The active matrix substrate 200 may further include TFTs using other semiconductors, in addition to the first and second TFTs 10A and 10B. The driver circuit may further include the first TFT 10A in addition to the second TFT 10B as the circuit TFT.

The configuration of the first and second TFTs 10A and 10B on the active matrix substrate 200 are the same as the previously described configuration in FIG. 1. These TFTs 10A and 10B are covered by a passivation film 19 and a planarizing film 21. In the first TFT 10A functioning as the pixel TFT, the gate electrode 15A is connected to the gate bus line (not shown), the source electrode 18sA is connected to the source bus line (not shown), and the drain electrode 18dA is connected to the pixel electrode 23P. In this example, the drain electrode 18dA is connected to the corresponding pixel electrode 23P inside an opening formed in the passivation film 19 and planarizing film 21. Video signals are supplied to the source electrode 18sA via the source bus line, and the necessary electric charge is written to the pixel electrode 23P based on the gate signal from the gate bus line.

In the active matrix substrate 200 of the present embodiment, the first TFT 10A, which has relatively low OFF leakage current during illumination, is used as the pixel TFT. Therefore, it is possible to more effectively reduce the writing frequency, which can thus lower power consumption. Meanwhile, the second TFT 10B, which uses a high mobility oxide semiconductor, is used as the circuit TFT constituting the respective circuits, and thus it is possible to shrink the circuit surface area and make the non-display area 60 smaller.

<Liquid Crystal Display Device>

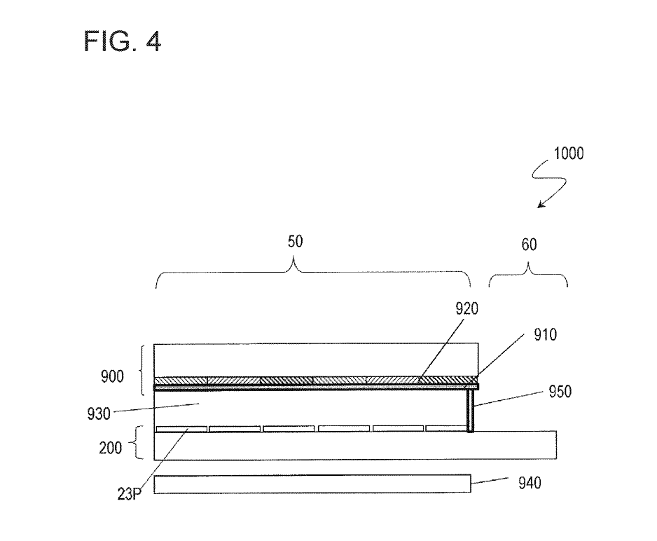

The active matrix substrate 200 of the present embodiment can be applied to a liquid crystal display device, for example. FIG. 4 is a schematic cross-sectional view showing one example of a liquid crystal display device 1000 that includes the active matrix substrate 200.

The liquid crystal display device 1000 includes the active matrix substrate 200, opposite substrate 900, liquid crystal layer 930 positioned between these substrates, and a backlight 940 that emits light for display toward the active matrix substrate 200. The liquid crystal layer 930 and backlight 940 are positioned in a region corresponding to the display area 50 of the active matrix substrate 200. The opposite substrate 900 has a color filter 920 and an opposite electrode 910. Although not shown, polarizing plates are arranged on the outer sides of both the active matrix substrate 200 and the opposite substrate 900.

Furthermore, although not shown, a scan line driver circuit that drives a plurality of scan lines (gate bus lines), a signal line driver circuit that drives a plurality of signal lines (data bus lines), and the like are positioned in the non-display area 60 of the active matrix substrate 200.

In the liquid crystal display device 1000, the liquid crystal molecules in the liquid crystal layer 930 are oriented toward the respective pixels in accordance with a difference in potential between the opposite electrode 910 and pixel electrode 23P, thus performing display.

<Manufacturing Method of Active Matrix Substrate 200>

Next, a method of manufacturing the active matrix substrate 200 of the present embodiment will be described.

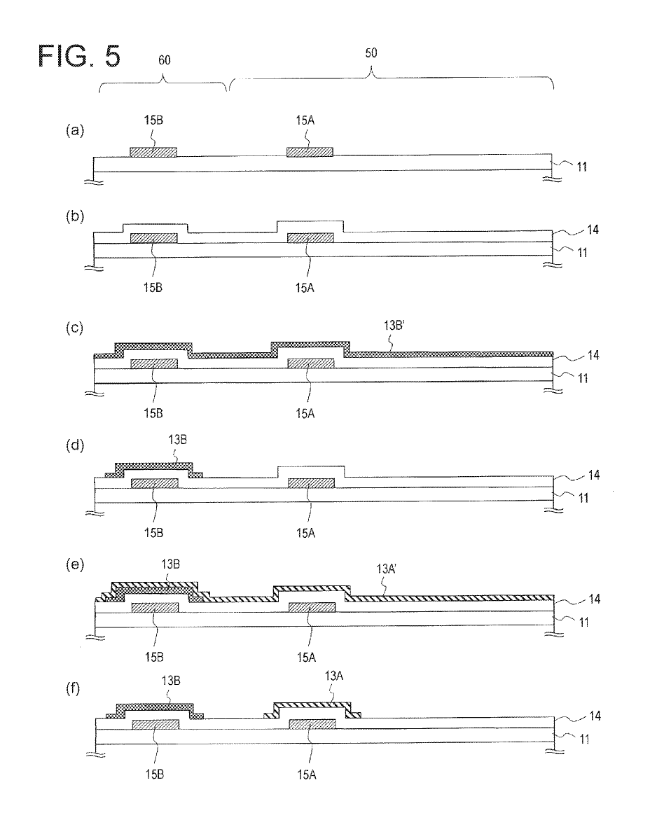

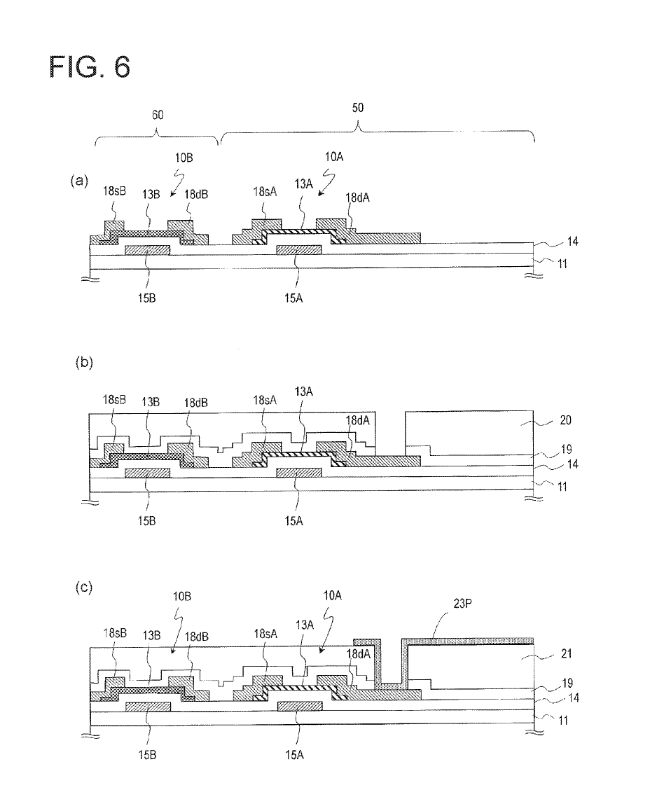

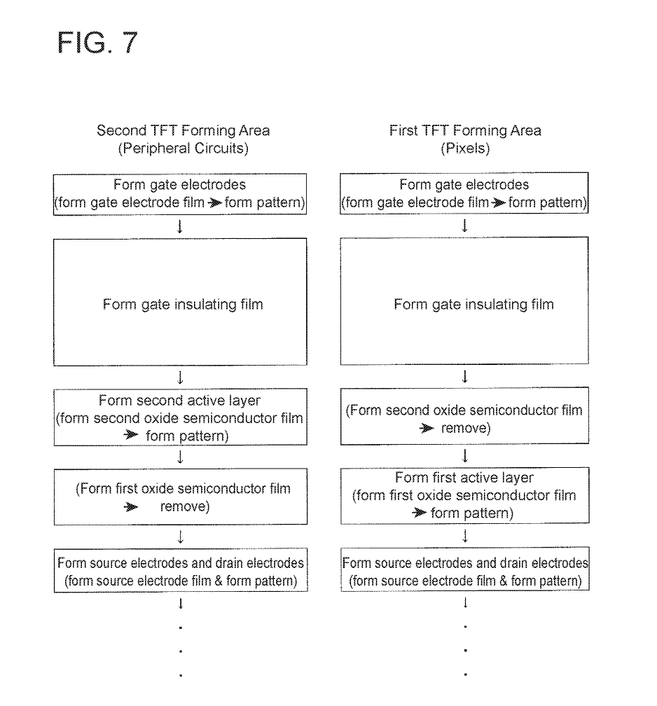

FIGS. 5(a) to 5(f) and 6(a) to 6(c) are cross-sectional views of steps of one example of a method of manufacturing the active matrix substrate 200. FIG. 7 is a view showing one example of the process flow for the first TFT 10A and second TFT 10B. The process flow is shown divided into the region where the first TFT 10A is formed (first TFT forming region) and the region where the second TFT 10B is formed (second TFT forming region). In this example, the first TFT forming region is positioned within the display area, and the second TFT forming region is positioned within the non-display area (driver circuit forming region).

First, a gate electrode film (thickness: 200 nm to 500 nm) is formed on the substrate 11 and then patterned. This forms the gate electrode 15A of the first TFT 10A, gate electrode 15B of the second TFT 10B, gate wiring lines (not shown), and the like. The substrate 11 can be various types of substrates such as a glass substrate, resin plate, resin film, or the like. The material of the gate electrode film has no particular limitations, and can be a metal such as aluminum (Al), tungsten (W), molybdenum (Mo), tantalum (Ta), chromium (Cr), titanium (Ti), copper (Cu), or a film containing an alloy of these. Alternatively, a multilayer film having a plurality of these films layered together may be used. The patterning method has no particular limitations, and it is possible to use a well-known photolithography and dry etching process.

Next, as shown in FIG. 5(b), the insulating layer (thickness: 50 nm to 130 nm, for example) 14 is formed to cover the gate electrodes 15A and 15B. The insulating layer 14 has no particular limitations, but mainly includes silicon oxide (SiOx), for example. The insulating layer 14 acts as the gate insulating film of the first and second TFTs 10A and 10B.

Next, as shown in FIG. 5(c), a second oxide semiconductor film 13B′ mainly containing the second oxide semiconductor is formed on the insulating layer 14. Sputtering, for example, is used to form an In—Sn—Zn—O semiconductor film (thickness: 10 nm to 120 nm) as the second oxide semiconductor film 13B′.

Thereafter, as shown in FIG. 5(d), the second oxide semiconductor film 13B′ is patterned to form the second active layer 13B in the second TFT forming region. The sections of the second oxide semiconductor film 13B′ positioned in the first TFT forming region are removed. The patterning of the second oxide semiconductor film 13B′ is performed by wet etching using oxalic acid as the etchant, for example.

Next, as shown in FIG. 5(e), a first oxide semiconductor film 13A′ mainly containing the first oxide semiconductor is formed on the insulating layer 14 and second active layer 13B. Sputtering, for example, is used to form a non-crystalline In—Ga—Zn—O semiconductor film (thickness: 10 nm to 120 nm) as the first oxide semiconductor film 13A′.

Thereafter, as shown in FIG. 5(f), the first oxide semiconductor film 13A′ is patterned to form the first active layer 13A in the first TFT forming region. The sections of the first oxide semiconductor film 13A′ positioned in the second TFT forming region are removed. At such time, etching is performed under parameters such that the etching speed for the first oxide semiconductor is greater than the etching speed for the second oxide semiconductor. This allows the second active layer 13B to remain without being removed. A nitric phosphoric acid etching solution is used as the etchant. An In—Sn—Zn—O semiconductor has resistance against nitric phosphoric acid etching solution, and thus it is possible to selectively etch only the In—Ga—Zn—O semiconductor.

The first and second active layers 13A and 13B are formed, and then a heat treatment is at 350° C. to 550° C., and preferably 400° C. to 500° C., for example. This heat treatment may be performed in a nitrogen atmosphere, a mixed nitrogen-oxygen atmosphere, or an oxygen atmosphere, for example. To avoid reduction reactions in the oxide semiconductor, it is preferable that a hydrogen atmosphere not be used, but rather an inactive gas or oxygen atmosphere be used. This crystallizes the In—Ga—Zn—O semiconductor. As a result, this forms the first active layer 13A into a crystalline In—Ga—Zn—O semiconductor layer. The In—Sn—Zn—O semiconductor need not crystalline, and may remain in a non-crystalline state.

The heat treatment may be performed on the first oxide semiconductor film 13A′ and second active layer 13B before patterning of the first oxide semiconductor film 13A′. Alternatively, the respective heat treatments may be performed after the second oxide semiconductor film 13B′ or second active layer 13B has been formed, and after the first oxide semiconductor film 13A′ or first active layer 13A has been formed. The heating temperature differs depending on the material of the oxide semiconductor, and is thus not limited to the temperatures listed as examples above.

The order in which the first and second active layers 13A and 13B are formed may be the opposite to the description above. In such a case, first the first active layer 13A containing the In—Ga—Zn—O semiconductor is formed. Thereafter, the second oxide semiconductor film 13B′ containing the In—Sn—Zn—O semiconductor is formed and patterned. At such time, if oxalic acid, for example, is used as the etchant, then it is possible to selectively etch the second oxide semiconductor film 13B′, and thus possible to form the second active layer 13B without removing the first active layer 13A. Even if the forming order is reversed, it is possible to perform a heat treatment similar to that described above.

Next, as shown in FIG. 6(a), the source and drain electrodes 18sA, 18dA, 18sB, and 18dB of the first TFT 10A and second TFT 10B are formed. Specifically, first sputtering is used to form a source electrode film, for example. Next, the source electrode film is patterned. This forms the source bus line (not shown), source electrode 18sA and drain electrode 18dA contacting the top surface of the first active layer 13A, and the source electrode 18sB and drain electrode 18dB contacting the top surface of the second active layer 13B. The source electrode film may be an aluminum film, for example. Alternatively, the source electrode film may be a multilayer film having an aluminum film as the top layer and/or a barrier metal film (e.g., Ti film, Mo film) as the bottom layer. The material of the source electrode film has no particular limitations. The source electrode film can contain a metal such as aluminum (Al), tungsten (W), molybdenum (Mo), tantalum (Ta), copper (Cu), chromium (Cr), or titanium (Ti), or an alloy or metal nitride of these. Alternatively, a multilayer film having a plurality of these films layered together may be used. A multilayer film (Ti/Al/Ti) in which a Ti film, Al film, and Ti film are layered in this order may be used, for example. The first TFT 10A and second TFT 10B are manufactured in the manner described above.

Next, as shown in FIG. 6(b), the passivation film (thickness: 150 nm to 700 nm, for example) 19 and planarizing film 21 are formed so as to cover the first TFT 10A and second TFT 10B.

In this example, the passivation film 19 is formed so as to contact the channel regions of the first and second active layers 13A and 3B. In the present embodiment, the bottom layer was an SiOx film (thickness: 100 nm to 400 nm, for example), and the top layer was an SiNx film (thickness: 50 nm to 300 nm, for example). In such a case, the bottom layer of the passivation film 19 constitutes the back channel of the TFTs 10A and 10B, and thus a SiOx film is preferable for the bottom layer, and a SiNx film having high passivation effects is preferable for the top layer to protect against moisture and impurities. The material of the passivation film 19 is not limited to these, and a combination of SiON, SiNO, or the like may be used instead. The planarizing film 21 is formed on the passivation film 19 by being coated, for example. The planarizing film 21 may be an organic insulating layer, or may be an insulating layer made of an acrylic transparent resin having positive photosensitivity, for example. Moreover, as described later, the planarizing film 21 may alternatively not be formed.

Thereafter, photolithography is used to form openings in the passivation film 19 and planarizing film 21 to expose the drain electrode 18dA of the first TFT 10A.

Next, as shown in FIG. 6(c), the pixel electrode 23P is formed on the planarizing film 21. The pixel electrode 23P can be formed using a transparent conductive film such as an ITO film (indium tin oxide), an IZO film, or a ZnO film (zinc oxide film). The active matrix substrate 200 of the present embodiment is formed in the manner described above.

In the method described above, the first TFT 10A and second TFT 10B can be integrally formed on the substrate 11. In particular, the steps for forming the gate electrodes, gate wiring line layers, source and drain electrodes, interlayer insulating film, and the like of the respective TFTs 10A and 10B can be shared. Moreover, the usage of the etchant can be distinguished to form the active layers 13A and 13B with differing oxide semiconductors on the same insulating layer 14. Accordingly, it is possible to inhibit an increase in manufacturing steps, manufacturing costs, etc.

The method of manufacturing the semiconductor device 100 is not limited to the above. If In—Ga—Zn—O semiconductors with differing compositions are used as the first and second oxide semiconductors, for example, then the etchant, etching parameters, and the like can be differed to make it difficult to pattern one of the oxide semiconductors. In such a case, it is possible to form the first active layer 13A and second active layer 13B on the insulating layer 14 as follows, for example.

First, the second active layer 13B is formed on the insulating layer 14 in a manner similar to above. Next, a resist film is formed on the second active layer 13B and insulating layer 14. An opening is provided in the area of the resist film where the first active layer 13A is formed. Next, the first oxide semiconductor film 13A′ containing the first oxide semiconductor is formed on the resist film and in the opening. Thereafter, the resist film and the portion of the first oxide semiconductor film 13A′ positioned on the resist film are removed (lift-off process). The portion of the first oxide semiconductor film 13A′ positioned inside the opening is not removed and serves as the first active layer 13A. The first active layer 13A may be formed first, and the second active layer 13B may be formed thereafter using a lift-off process.

### Embodiment 2

Embodiment 2 of the semiconductor device according to the present invention will be described.

The semiconductor device (active matrix substrate) of the present embodiment differs from the active matrix substrate 200 shown in FIG. 2 in part or all of the second TFTs having a double-gate structure.

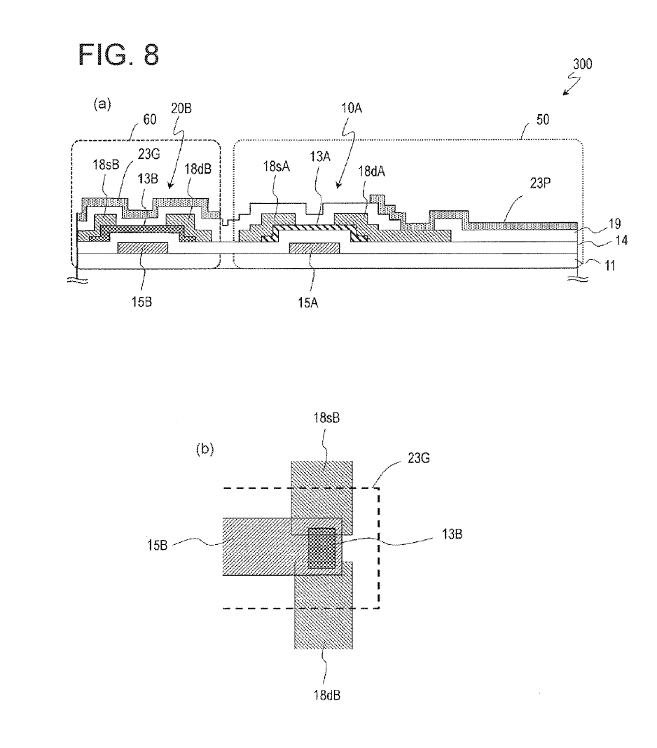

FIG. 8(a) is a cross-sectional view illustratively showing the active matrix substrate 300 of the present embodiment. In FIG. 8(a), constituting elements that are similar to the active matrix substrate 200 shown in FIG. 2 are given the same reference characters.

The active matrix substrate 300 includes a plurality of first TFTs 10A as pixel TFTs and a plurality of second TFTs as circuit TFTs. Part or all of the second TFTs are TFTs 20B having a double-gate structure. The part or all of the second TFTs 20B having a double-gate structure are called “double-gate TFTs.” The other second TFTs constituting the peripheral circuits may have the bottom-gate structure shown in FIG. 2.

The double-gate TFT 20B has a gate electrode (bottom gate electrode) 15B positioned on the substrate 11 side of the second active layer 13B, and additionally a top gate electrode 23G positioned above the second active layer 13B. The top gate electrode 23G may be formed using the same conductive film as the pixel electrode 23P, for example. The plan view of the double-gate TFT 20B is illustratively shown in FIG. 8(b). As shown in FIG. 8(b), the top gate electrode 23G may be positioned so as to cover the entirety of the island-shaped second active layer 13B.

The active matrix substrate 300 does not need to have a planarizing film. As shown in the drawing, the pixel electrode 23P and top gate electrode 23G may be positioned on the passivation film 19 covering the first and second TFTs 10A and 10B without an intermediary planarizing film therebetween. In such a case, the insulating layer 14 and passivation film 19 function as the gate insulating film of the double-gate TFT 20B. Not providing the planarizing film confers the benefit of being able to effectively apply the electric field from the top gate electrode 23G.

In the second TFT 20B having the double-gate structure, applying the gate voltage to both the second gate electrode 15B and top gate electrode 23G makes it possible to improve the apparent mobility of the second active layer 13B. Thus, it is possible to further reduce the size of the second TFT 20B, which makes it possible to more effectively reduce the size of the frame region. The top gate electrode 23G may be set to a fixed voltage. This can reduce variation in the threshold of the second TFT 20B, thus making it possible to improve yield.

The uses and formation areas of the first TFTs 10A and second TFTs 10B & 20B are not limited to the uses and areas illustratively described in the above embodiment. In a device having a plurality of TFTs, the first TFTs 10A and second TFTs 10B should be differentiated depending on the characteristics required of the TFTs. The first TFTs 10A can be used not only as the pixel TFTs within the display area 50, but also as the circuit devices in the non-display area 60. In second TFTs 10B using a high-mobility oxide semiconductor, the threshold voltage may be 0V or below, for example. In such a case, a portion of the TFTs constituting the peripheral circuits may, as necessary, serve as the first TFTs 10A, which have threshold voltages that are easier to control. Accordingly, the first TFTs 10A and second TFTs 10B may be provided together in the peripheral circuits of the non-display area 60.

Furthermore, the embodiments of the present invention are not limited to an active matrix substrate, and are applicable to a variety of devices that include a plurality of thin film transistors. The embodiments of the present invention can be widely applied to circuit substrates, display devices, electronics, and the like, for example. This would make it possible to enhance the performance and reliability of the semiconductor device and reduce the size by using TFTs that correspond to the required characteristics.

### INDUSTRIAL APPLICABILITY

The embodiments of the present invention can be widely applied to devices, electronics, and the like that have a plurality of thin film transistors. The embodiments of the present invention can be applied to circuit substrates such as active matrix substrates, display devices such as liquid crystal display devices, organic electroluminescent (EL) display devices and inorganic electroluminescence display devices, imaging devices such as radiation detecting devices, image sensors, and electronic devices such as image input devices and fingerprint reading devices.

Description of Reference Characters
10A first thin film transistor (TFT)
10B, 20B second thin film transistor (TFT)
11 substrate
13A first active layer
13B second active layer
13cA, 13cB channel region
13dA, 13 dB drain contact region
13sA, 13sB source contact region
14 insulating layer
15A, 15B gate electrode
18dA, 18dB drain electrode
18sA, 18sB source electrode
19 passivation film
20 planarizing film
23P pixel electrode
23G top gate electrode
50 display area
60 non-display area
100 semiconductor device
200 active matrix substrate
1000 liquid crystal display device

1. A semiconductor device, comprising:
a substrate;
a first thin film transistor supported on the substrate and having a first active layer that primarily contains a first oxide semiconductor; and
a second thin film transistor supported on the substrate and having a second active layer that primarily contains a second oxide semiconductor with a mobility that is higher than the first oxide semiconductor,
wherein the first active layer and the second active layer are positioned on a same insulating layer and contact said same insulating layer.

2. The semiconductor device according to claim 1, wherein an OFF current of the first thin film transistor when illuminated by visible light is less than an OFF current of the second thin film transistor when illuminated by visible light.

3. The semiconductor device according to claim 1, wherein an OFF current of the first thin film transistor when illuminated by light with a wavelength of 450 nm and an intensity of 50 lux is less than an OFF current of the second thin film transistor when illuminated by light with a wavelength of 450 nm and an intensity of 50 lux.

4. The semiconductor device according to claim 1, wherein the mobility of the second oxide semiconductor is greater than 10 cm²/Vs.

5. The semiconductor device according to claim 1, wherein an OFF current of the first thin film transistor when illuminated by light with a wavelength of 450 nm and an intensity of 50 lux is less than or equal to 1×10⁻¹³ amperes.

6. The semiconductor device according to claim 1, wherein the first oxide semiconductor is an In—Ga—Zn—O semiconductor.

7. The semiconductor device according to claim 1, wherein the second oxide semiconductor is an In—Sn—Zn—O semiconductor.

8. The semiconductor device according to claim 1, wherein the first and second oxide semiconductors are both In—Ga—Zn—O semiconductors, and a mole ratio of indium to all metal elements in the first oxide semiconductor is smaller than a mole ratio of indium to all metal elements in the second oxide semiconductor.

9. The semiconductor device according to claim 1, wherein a gate electrode of the first thin film transistor and a gate electrode of the second thin film transistor are positioned on a side of the first and second active layers facing the substrate.

10. The semiconductor device according to claim 9, wherein the second thin film transistor further includes another gate electrode positioned on a side of the second active layer opposite to the substrate.

11. The semiconductor device according to claim 1, further comprising:
a display area having a plurality of pixels, and a driver circuit formation area disposed in an area outside the display area and having a driver circuit,
wherein a plurality of the second thin film transistors form said driver circuit in said driver circuit formation area, and
wherein a plurality of the first thin film transistors are positioned in the respective pixels in the display area.

12. The semiconductor device according to claim 1, further comprising a backlight on a rear surface side of the substrate.

13. A liquid crystal display device including the semiconductor device according to claim 11, said liquid crystal display device comprising:
an opposite substrate held so as to face the substrate;
a liquid crystal layer between the substrate and the opposite substrate; and
a backlight on a rear surface side of the substrate.

14. A method of manufacturing a semiconductor device including a first thin film transistor and a second thin film transistor, the method comprising:
(A) forming, on a substrate having an insulating surface, gate electrodes of the first and second thin film transistors and a gate insulating layer covering the gate electrodes of the first and second thin film transistors;
(B) forming, on the gate insulating layer, a first active film of the first thin film transistor and a second active film of the second thin film transistor in this order or an opposite order;
(b1) forming a first film made of a first oxide semiconductor and patterning the first film to form the first active layer;
(b2) forming a second film made of a second oxide semiconductor with a mobility that is higher than the first oxide semiconductor and patterning the second film to form the second active layer; and
(C) forming, on the first and second active layers, source electrodes and drain electrodes of the first and second thin film transistors.

15. The method of manufacturing the semiconductor device according to claim 14,
wherein a first etchant is used to pattern the first film in the step (b1) of forming the first film, and
wherein a second etchant that differs from the first etchant is used to pattern the second film in the step (b2) of forming the second film.

16. The method of manufacturing the semiconductor device according to claim 15,
wherein the first oxide semiconductor is an In—Ga—Zn—O semiconductor, and the second oxide semiconductor is an In—Sn—Zn—O semiconductor, and
wherein the first etchant is a nitric phosphoric acid etchant and the second etchant is oxalic acid.

17. The method of manufacturing the semiconductor device according to claim 14, wherein the step (B) of forming the first active film and the second active film further includes performing a first heat treatment on the first active layer or the first film and performing a second heat treatment on the second active layer or the second film, said first heat treatment and said second heat treatment being performed simultaneously.
